(19) United States
(12) Patent Application Publication
(10) Pub. No.: US 2010/0258458 A1
(43) Pub. Date: Oct. 14, 2010

(54) SEALING OF HOUSINGS BY MEANS OF SEALANTS

(75) Inventors: Franz Nömmer, Dorfen (DE); Antonius Rossberger, Sindelsdorf (DE)

Correspondence Address: BACON & THOMAS, PLLC, 625 SLATERS LANE, FOURTH FLOOR, ALEXANDRIA, VA, 22314-1176, US

(73) Assignee: Giesecke & Devrient GmbH

(21) Appl. No.: 12/808,310

(22) PCT Filed: Dec. 16, 2008
(86) PCT No.: PCT/EP2008/010720

§ 371 Date: Jun. 15, 2010

(30) Foreign Application Priority Data
Dec. 17, 2007 (DE) 10 2007 060 760.3

(51) Int. Cl. F16J 15/14; H05K 5/06

(52) U.S. Cl. 206/305; 277/316; 29/593

(57) ABSTRACT

A sensor housing (10) is sealed against the penetration of dust by means of sealing compound (7) by grooves at the interfaces of abutting housing members (1, 2, 3; 8, 9) being so configured that they form at least one channel (4) in the assembled state. After assembly and fixing of the housing members the sealing compound (7) is injected into the channel (4) through an inlet opening (5). This permits even complex contact geometries to be mutually sealed in a simple manner.

This invention relates to a method for sealing a housing assembled from several housing members against the penetration of dust between interfaces of abutting housing members. Furthermore, the invention relates to a suitably adapted housing kit comprising several housing members. The invention is of special importance for housings in which sensors are received which are used in the checking of value documents.

Sensor housings, in particular housings with optical sensors, must be configured to be dust-tight in order for the latter to lastingly deliver reliable measuring results. The sensor housings are usually assembled from several housing members, with abutting housing members being sealed with foam rubber or by sealing compound. For this purpose the interfaces of the abutting housing members are provided with sealing compound, for example silicone, or equipped with foam rubber seals before assembly. However, this can be very difficult and is sometimes impossible when elaborately shaped housing components abut, for example in the case of undercuts and other three-dimensional contact geometries.

Hence, it is the object of the present invention to propose a method for sealing a housing assembled from several housing members against the penetration of dust which allows reliable sealing even in the case of complex contact geometries. A further object is to state a housing kit suitable for carrying out this method.

The inventive method provides for first assembling the housing members to be mutually sealed and fixing them mutually, so that a complete housing or at least a partial housing is formed which is later expanded into a complete housing. A complete housing is understood to be a housing of completely closed construction which has no dust-permeable openings. The housing members are assembled such that at least one closed channel is formed between the housing members to be mutually sealed, in particular at the abutting interfaces between the abutting housing members. For this purpose there can be provided for example grooves in one of the two, or in both, abutting interfaces which then form the closed channel in cooperation with the respective other interface or the respective other groove. A closed channel is to be understood for the purposes of the present invention as a channel possessing a channel cross section closed all around. In other words, the channel extends completely within the housing wall after the assembly of the abutting housing members. This does not exclude the channel possessing openings to the outside at its beginning, and optionally at its end. Thus, the channel possesses at least one inlet opening and one or optionally several outlet openings. Through the inlet opening, sealing compound is filled into the channel after the housing members have been assembled and mutually fixed. In so doing, the sealing compound is introduced between the abutting interfaces of the housing members to be sealed. Filling in the sealing compound is continued until the channel is filled with sealing compound over its total length.

The air displaced out of the channel while the sealing compound is being filled in can escape along the channel and/or through narrow cracks between the interfaces. However, on account of its surface tension the sealing compound cannot pass through cracks between the abutting interfaces, but spreads along the channel. Preferably, the channel possesses at least one outlet opening from which the sealing compound can exit. This has the advantage that the exit of sealing compound from the outlet opening makes it possible to visually check in a simple manner whether the filling process is finished. If the channel branches into several channel branches, at least one such outlet opening is preferably provided for each channel branch. In the case of such branches it is advantageous to provide the outlet openings of the channel branches with a tapered cross-sectional area in comparison to the cross section of the channel branch, in order for the reduced cross section to delay the sealing compound flow. In this manner it is possible to fill all the channel branches with sealing compound completely and uniformly. For further improving the filling of several channel branches there can also be provided several inlet openings, e.g. one for each channel branch.

The present invention permits extremely complex housing members to be mutually sealed in reliably dust-tight fashion. Sealing is thus also possible in the case of undercuts, i.e. for example in such cases where the interfaces forming the channel cannot be simply placed on each other during assembly but must be pushed past each other to position the housing members. In such cases it is not possible to provide conventional foam rubber seals or silicone sealing compounds on the interfaces before assembly. In comparison, in the inventive method the closed channel is only formed upon assembly, and then produces a reliable seal by being filled with sealing compound in a simple manner after assembly.

Because the sealing compound is only injected after assembly of the housing or the partial housing, there cannot occur any smearing of the sealing compound upon assembly of the housing members. This is of special importance in high-quality sensor housings, in particular in an optical sensor housing which receives a window through which the sensor can acquire measuring signals and which must remain clean. The inventive method permits a sensor window to be reliably and cleanly sealed from the sensor housing. Upon sealing of a sensor window the channel for the sealing compound is preferably formed between a groove in the sensor housing and the surface of the window.

The inventive housing or partial housing is preferably employed for receiving one or more sensors for checking value documents which are used in a machine for value-document processing. In the sensor housings there can be disposed e.g. measuring elements of optical and/or magnetic and/or capacitive sensors. Said sensors are usually disposed on a transport path along which value documents are transported past the sensors.

The assembly and the fixation of the housing members can be optimized when the housing members are adapted to be slipped into each other. Alternatively or additionally to the ability of the housing members to be slipped into each other, the housing members are fixable relative to each other by a snap connection. This may be sufficient for simple housing member geometries. Alternatively or in addition thereto, in particular when the sealing compound is filled into the channel at high injection pressure, the housing members can be screwed together or firmly interconnected in another manner.

Ideally, the functional capability of the sensor received in the housing is checked before the sealing compound is filled into the channel. If the check turns out negative, the housing or partial housing can be disassembled without problems, for example by undoing the relative fixation of the housing members which has been brought about by slipping into each other and/or snap connections and/or screwing. After disassembly the functional capability of the sensor and/or of components of the sensor can be brought about, optionally individual components replaced, and the housing or partial housing reassembled. The filling of the channel with sealing compound is then effected only after a successful function check. This makes clear a further advantage achieved by the invention, which is that in the case of a lack of functional capability of the sensor there is no need to remove sealing compound and clean the interfaces in connection with dismantling.

The sealing compound used may be a permanently elastic material adhering well to the interfaces, in particular silicone or acrylic, provided it has no appreciable volume shrinkage. If sensitive fittings are present, attention should be paid that the sealing compound does not emit any harmful gases, such as acetic acid, because such gases can attack sensitive surfaces. The selection of the employed sealing compound also depends on the channel cross section and the channel length. The longer the channel is and/or the smaller the channel cross section is, the more flowable the sealing-compound material must be.

Upon the use of silicone as the sealing compound, a cross section of at least 10 mm², preferably at least 15 mm², in particular about 16 mm², has turned out to be the optimal in the case of an optical sensor housing of customary size. The ratio of height and width of the channel cross section, or, in more general terms, the ratio X of the two most extreme cross-sectional dimensions, should in any case in the linear portions of the channel be continuously 0.8<X<1.2 and preferably approximately X=1. At intersection points or branch points of the channel the cross-sectional ratio can be chosen differently. The ideal channel cross section is square or in particular circular. It is not necessary for the channel cross section to be formed by the interfaces of two abutting housing members. It is also possible that the channel is formed by three or more adjacent housing members.

Hereinafter the invention will be described by way of example with reference to the accompanying drawings. Therein are shown:

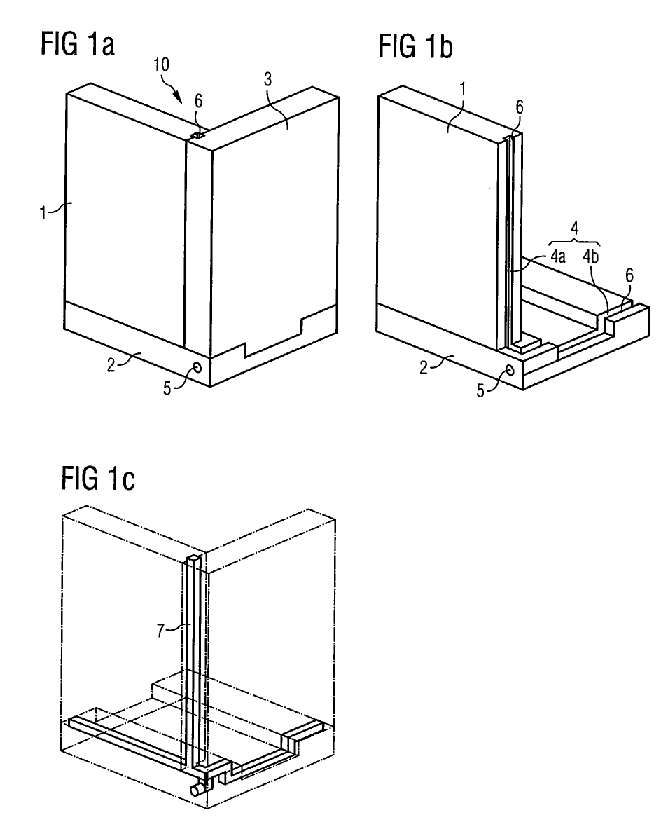

FIG. 1a a partial housing consisting of several housing members,

FIG. 1b the partial housing from FIG. 1a with a missing wall before sealing by means of sealing compound,

FIG. 1c the channel filled with sealing compound in the partial housing from FIG. 1a,

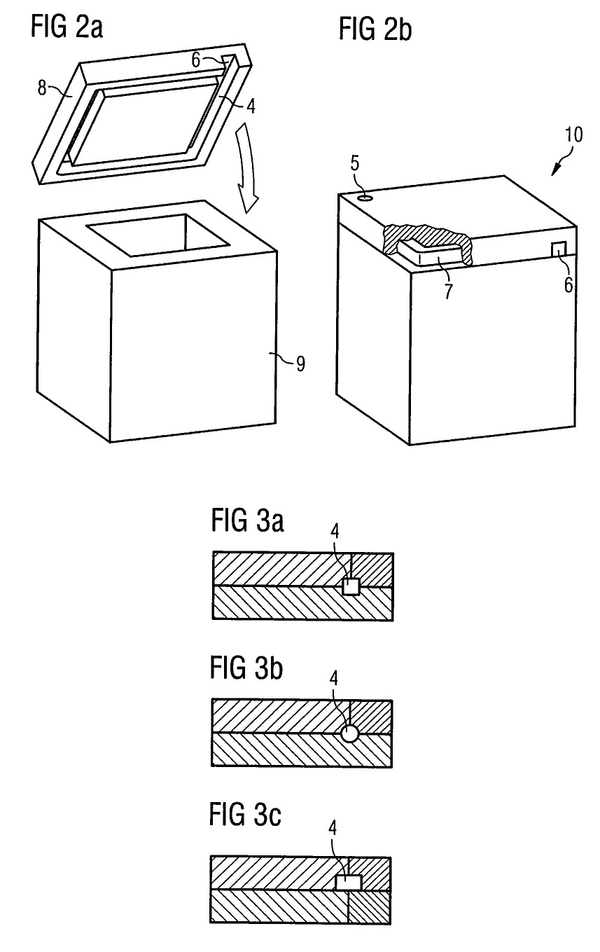

FIG. 2a a housing consisting of two housing members to be interconnected, before assembly and sealing,

FIG. 2b the housing from FIG. 2a after assembly and sealing, partly in cross section,

FIGS. 3a to 3c different sealing channels formed between more than two adjacent housing members, in cross section.

FIG. 1a shows a partial housing 10 comprising three housing members 1, 2 and 3 in the assembled state. FIG. 1b shows the same partial housing without housing member 3. In FIG. 1b one can see the course of two channel branches 4a, 4b of a sealing-compound channel 4. The channel branches 4a, 4b are realized as grooves in the abutting interfaces of the housing members 1, 2 and 3. With the housing member 3 there thus results a closed sealing-compound channel 4. The sealing-compound channel 4 has one inlet opening 5 and three outlet openings 6, one of which can be seen in FIG. 1a and two in FIG. 1b.

The sealing compound is applied into the inlet opening 5 using common dispensers and nozzles as are offered by sealing-compound manufacturers. For example, the sealing compound can be injected into the inlet opening 5 by means of a dispenser operated with compressed air (e.g. from the company GLT). The processing conditions, in particular the cleanness of the grooves, processing temperature and processing time, are to be maintained as prescribed by the sealing-compound manufacturer. To allow simple handling there is preferably chosen a sealing compound that is processable at ambient temperature. Ideally, the form and the cross section of the inlet opening 5 are adapted to the form and the cross section of the dispenser, accordingly being preferably circular.

If only one outlet opening 6 is provided (see hereinafter FIGS. 2a and 2b), the cross-sectional geometry of the outlet opening is unimportant. However, if there are provided branches of the sealing-compound channel 4 into several channel branches each possessing at the end an outlet opening 6 for the exit of excess sealing compound, as in the present exemplary embodiment, the cross section of the outlet openings is preferably configured smaller than the narrowest cross sections of the channel 4 and of the channel branches 4a, 4b. In this case the cross section of the outlet openings of the channel branches is preferably also smaller than the cross section of the inlet opening. The smaller cross-sectional area of the outlet openings increases the flow resistance, so that when the sealing compound is filled in, the channel 4 first fills completely with sealing compound before excess sealing compound exits from the outlet openings. As soon as this is the case it can be assumed that the filling of the channel 4 and of the channel branches 4a, 4b is finished. FIG. 1c shows the ultimately resulting seal 7. Depending on the type of sealing compound it may be necessary to let it cure before the housing is employed.

FIGS. 2a and 2b show the above-described process of housing sealing by a second, simple example. Here a cover 8 is placed onto a container-like housing body 9. The housing involved may be for example an optical-sensor housing with a window (not shown here) and an optical sensor (likewise not shown) received in the housing body 9 for detecting light intensities passing through the window. The dimensions of the sensor housings are typically in the range of 5 cm to 25 cm. FIG. 2a shows the housing cover 8 with a groove formed therein which forms the channel 4 in cooperation with the housing body 9. An inlet opening 5 is present at the top in the cover so as to be readily accessible. From said inlet opening 5 there extend two channel branches which meet at a lateral outlet opening 6. Sealing compound is injected into the inlet opening 5 without bubbles. As soon as sealing compound exits from the outlet opening 6, this is a sign of a successful filling process. The outlet opening 6 is so disposed that it is readily visible from outside. The partially sectional representation in FIG. 2b shows the seal 7 formed by the sealing compound.

FIGS. 3a to 3c show schematically several possibilities of how the sealing-compound channel 4 can be formed by more than two, here by three or four, housing members. In so doing, the housing cross section can be square, circular or rectangular or also assume other shapes.

1-24. (canceled)

25. A method for sealing a housing having several housing members against the penetration of dust, wherein at least two of the housing members abut and are mutually sealed by means of sealing compound, comprising the steps of:
a) assembling and fixing several of the housing members for forming the housing or a partial housing such that between the housing members to be mutually sealed there is formed at least one closed channel which has at least one inlet opening for the sealing compound, and
b) filling the at least one channel with sealing compound through the at least one inlet opening.

26. The method according to claim 25, wherein the channel has at least one outlet opening for the sealing compound whose cross-sectional area is smaller than a narrowest channel cross-sectional area, wherein the filling step is continued until the sealing compound exits at all of the at least one outlet opening.

27. The method according to claim 25, including fixing the housing members relative to each other by being slipped into each other and/or by one or more snap connections and/or by screwing.

28. The method according to claim 25, including using as the sealing compound a permanently elastic material.

29. The method according to claim 25, including forming the channel such that the aspect ratio X of the two most extreme dimensions of a channel cross section in the linear portions of the channel is 0.8<X<1.2.

30. The method according to claim 29, wherein the aspect ratio X is X=1, so that the channel cross section is circular or square.

31. The method according to claim 29, wherein the channel cross section is so formed that it is at least 10 mm².

32. The method according to claim 25, including providing the channel with exactly one inlet opening for the filling in of the sealing compound.

33. The method according to claim 25, including, upon assembly and fixing of the housing members, forming a single, optionally branched channel.

34. The method according to claim 25, including the further step of checking the housing or partial housing and/or the functional capability of a sensor received in the housing or partial housing and/or of components of a sensor received in the housing or partial housing before carrying out step b) and, if the check turns out negative, disassembling the housing or partial housing and carrying out step a) again.

35. The method according to claim 25, including providing in the housing or partial housing an optical sensor, and providing at least one of the housing members with a window or configuring the at least one of the housing members as a window.

36. A housing kit comprising several housing members from which a housing or at least a partial housing can be assembled, wherein interfaces along at least two of the housing members that abut in the assembled state of the housing or partial housing are so configured that in the assembled state of the housing or partial housing there is formed between the interfaces at least one closed channel which has at least one inlet opening for the filling in of sealing compound and optionally at least one outlet opening for the exit of sealing compound filled into the channel.

37. The housing kit according to claim 36, comprising slip-in connections and/or snap connections on at least one of the several housing members, so that the housing members are fixable relative to each other by being slipped into each other.

38. The housing kit according to claim 36, including screw connections on at least one of the several housing members, so that the housing members are fixable relative to each other by being screwed together.

39. The housing kit according to claim 36, wherein the channel formed in the assembled state of the housing or partial housing is configured such that the aspect ratio X of the two most extreme dimensions of a channel cross section in the linear portions of the channel is 0.8<X<1.2.

40. The housing kit according to claim 39, wherein the aspect ratio X is X=1, so that the channel cross section is circular or square.

41. The housing kit according to claim 39, wherein the channel cross section is so configured that it is at least 10 mm².

42. The housing kit according to claim 36, wherein the cross-sectional area of the at least one outlet opening is configured smaller than a narrowest channel cross-sectional area.

43. The housing kit according to claim 36, wherein in the assembled state, there is formed a single, optionally branched channel.

44. The housing kit according to claim 36, wherein the housing members have at least one window.

45. A housing or partial housing formed from a housing kit according to claim 36, wherein the housing members are mutually sealed, for example against the penetration of dust, by means of a sealing compound filling the at least one channel.

46. The housing according to claim 45, wherein the sealing compound comprises a permanently elastic material.

47. The housing according to claim 45, wherein, in the case of the presence of at least one outlet opening, the sealing compound closes the outlet opening.

48 The housing according to claim 45, wherein the housing there is provided a sensor.
